(19) United States
(12) Patent Application Publication
(10) Pub. No.: US 2015/0371855 A1
(43) Pub. Date: Dec. 24, 2015

(54) APPARATUS FOR ETCHING TWO-DIMENSIONAL MATERIAL AND METHOD OF PATTERNING TWO-DIMENSIONAL MATERIAL USING THE SAME

(71) Applicant: Samsung Electronics Co., Ltd., Suwon-si (KR)

(72) Inventors: Kiyeon YANG, Seongnam-si (KR); Namjeong KIM, Gwangju-si (KR); Haesung KIM, Hwaseong-si (KR)

(21) Appl. No.: 14/721,395

(22) Filed: May 26, 2015

(30) Foreign Application Priority Data
Jun. 19, 2014 (KR) 10-2014-0075055

(51) Int. Cl. H01L 21/04; H01L 21/67; H01L 29/16; H01L 21/306; H01L 21/3065

(52) U.S. Cl. CPC H01L 21/042; H01L 21/30604; H01L 21/3065; H01L 29/1606; H01L 21/67069; H01L 21/67075

(57) ABSTRACT

According to example embodiments, an apparatus for etching a two-dimensional material layer includes a stage configured to support an etching target including graphene on the stage, a light source configured to emit light having a wavelength that is shorter than a wavelength of visible light, a mask imprinted with a pattern for transferred onto the etching target, a fluid inlet configured to supply a fluid over the etching target, and a fluid outlet configured to absorb a residue and a reaction product after the fluid is supplied over the etching target using the fluid inlet.

### RELATED APPLICATION

This application claims priority under 35 U.S.C. §119 to Korean Patent Application No. 10-2014-0075055, filed on Jun. 19, 2014, in the Korean Intellectual Property Office, the disclosure of which is incorporated herein in its entirety by reference.

### BACKGROUND

1. Field

The present disclosure relates to an apparatus for etching a material layer and a method of patterning the material layer using the same, and more particularly, to an apparatus for etching a two-dimensional material layer and a method of patterning the two-dimensional material layer using the same.

2. Description of Related Art

Graphene may be a one-atom thick, two-dimensional structure where carbon atoms are connected by a sp² bond. The carbon atoms are of a honeycomb structure in the graphene. An electric current which flows per unit area in graphene at room temperature is 100 times or greater as much as that in copper. Also, graphene may conduct electricity at a speed of 100 times or greater as high as silicon. Also, graphene has thermal conductivity of two times or greater as high as that in diamond and a mechanical strength of 200 times or greater as high as steel. As graphene may be made to exhibit semiconductor properties by forming graphene in nanoribbons, thereby tuning band gaps thereof. Graphene may be considered a next-generation material for semiconductor device applications.

Graphene may be structurally weak. Graphene may have weak adhesion to a lower substrate. Growing graphene directly on a substrate may be difficult because graphene may be a one- atom thick thin film composed of carbon. Particularly, graphene may be chemically vulnerable. A surface of graphene may be polluted in a process where a wet chemical is used.

Studies on a new patterning technology excluding the process where the wet chemical is used may be desirable because the surface of graphene may be polluted during a process of coating a photoresist and a process of developing the same in a patterning process where a related photolithography technology is used.

Accordingly, a method of using an electron beam has been introduced. As the electron beam has a high energy and may be selectively irradiated in general, active studies on a direct patterning of graphene where the electron beam is used are in progress.

However, related lithography technologies where the electron beam is used, such as spot e-beam lithography, variable shaped beam (VSB), and mask-less lithography (ML2) may have a low productivity. The low productivity may be undesirable for manufacturing semiconductor devices.

### SUMMARY

Provided is an apparatus for etching a two-dimensional material layer, which may limit (and/or prevent) graphene degradation which may arise during a graphene patterning process and may also raise productivity.

Provided is a method of patterning the two-dimensional material layer using the apparatus.

Additional aspects will be set forth in part in the description which follows and, in part, will be apparent from the description, or may be learned by practice of the presented embodiments.

According to example embodiments, an apparatus for etching a two-dimensional material layer includes a stage configured to support an etching target including graphene on the stage, a light source configured to emit light having a wavelength that is shorter than a wavelength of visible light, a mask imprinted with a pattern for transferring to the etching target, a fluid inlet configured to supply a fluid over the etching target, and a fluid outlet configured to absorb a residue and a reaction product after the fluid is supplied over the etching target using the fluid inlet.

In example embodiments, the light source may be an extreme ultraviolet (EUV) light source or an X-ray light source. For example, the light source may be a light source which emits EUV whose wavelength is 13.5 nm or a light source which emits X-ray whose wavelength is shorter than 13.5 nm.

In example embodiments, the mask may be a transmitting mask that is configured to transmit light incident from the light source.

In example embodiments, the mask may be a reflecting mask that is configured to reflect light incident from the light source. The apparatus may include a reflector that is configured to reflect the light incident from the reflecting mask to the etching target.

In example embodiments, the fluid may be a gas or a liquid fluid. The fluid may react with the etching target to form a volatile reaction product.

In example embodiments, the gas fluid may be oxygen or an oxygen ion.

In example embodiments, the liquid fluid may include an element that reacts with carbon (C) of the graphene to form a gaseous substance.

According to example embodiments, an apparatus for etching a two-dimensional material layer includes a stage configured to support an etching target including graphene on the stage, a first light source configured to irradiate the first light on a first region of the etching target, a second light source configured to emit a second light that forms an interference pattern with the first light in the first region, a fluid inlet configured to supply a fluid over the etching target, and a fluid outlet configured to absorb a residue and a reaction product after the fluid is supplied over the etching target using the fluid inlet.

In example embodiments, the fluid may be a gas or a liquid fluid that reacts with the etching target to form a volatile reaction product.

According to example embodiments, a method of patterning a two-dimensional material layer includes: disposing a etching target on a stage, the etching target including graphene; irradiating light on the etching target the light having a wavelength that is shorter than a wavelength of visible light; supplying a fluid over the etching target, and removing a fluid residue and a fluid reaction product on the etching target.

In example embodiments, the irradiating the light on the etching target may include irradiating light incident from a mask.

In example embodiments, the fluid may be supplied before or simultaneously when the light is irradiated on the etching target.

In example embodiments, the fluid may be a gas or a liquid fluid that reacts with the etching target to form a volatile reaction product.

According to example embodiments, a method of patterning a two-dimensional material layer includes” disposing an etching target on a stage, the etching target including graphene; irradiating first light on a first region of the etching target, the first light having a wavelength that is shorter than a wavelength of visible light; irradiating second light on the first region of the etching target, the second light forming an interference pattern with the first light on the first region, the second light having a wavelength that is shorter than the wavelength of visible light; supplying a fluid over the etching target,; and removing a fluid residue and a fluid reaction product from the etching target.

In example embodiments, the supplying the fluid may be performed before the first and the second light are irradiated on the first region of the etching target. Alternatively, the supplying the fluid, the irradiating first light, and the irradiating second light may be performed simultaneously.

### BRIEF DESCRIPTION OF THE DRAWINGS

These and/or other aspects will become apparent and more readily appreciated from the following description of non-limiting embodiments, taken in conjunction with the accompanying drawings in which:

FIG. 1 is a cross sectional view illustrating an apparatus for etching a two-dimensional material layer according to example embodiments;

FIG. 2 is a cross sectional view illustrating a composition of the material layer of FIG. 1;

FIG. 3 is a cross sectional view illustrating an example of a selective reaction between a fluid and the two-dimensional material layer in the etching apparatus of FIG. 1;

FIG. 4 is a cross sectional view illustrating an apparatus for etching a two-dimensional material layer according to example embodiments; and

FIG. 5 is a cross sectional view illustrating an apparatus for etching a two-dimensional material layer according to example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference characters and/or numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Reference will now be made in detail to an apparatus for etching a two-dimensional material layer and a method of etching the two-dimensional material layer using the same according to example embodiments.

An apparatus for etching a two-dimensional material layer (which will be shortly called an etching apparatus) according to example embodiments will be described as well as a method of etching the two-dimensional material layer.

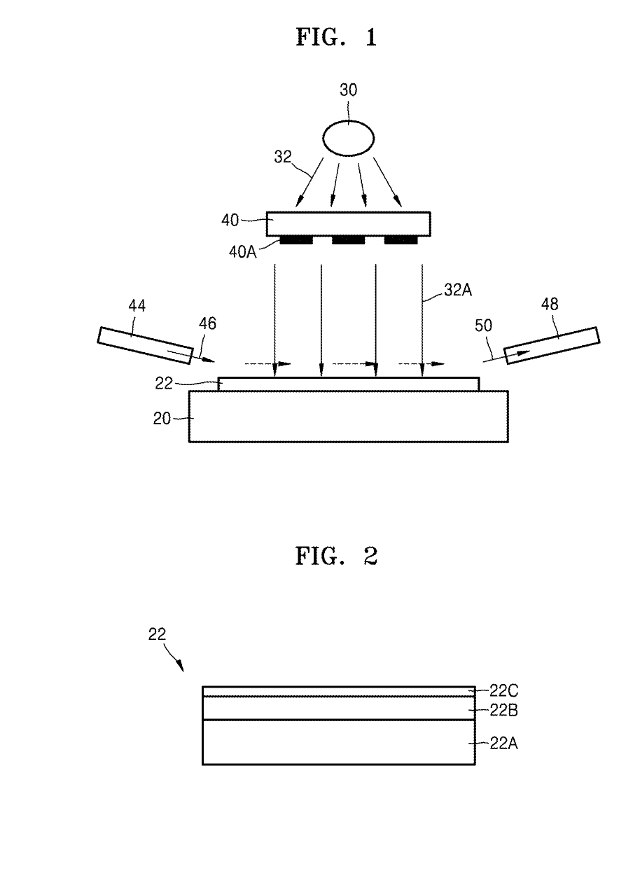

FIG. 1 illustrates an apparatus for etching a two-dimensional material layer according to example embodiments.

Referring to FIG. 1, the etching apparatus includes a stage 20 on which the etching target is to be disposed, a light source 30 which faces) the stage 20 (or alternatively may be arranged to not face the stage 20), and a mask 40 provided between the stage 20 and the light source 30. The mask 40 may be a transmitting mask. The mask 40 is disposed apart from the light source 30 and the stage 20. The light source 30 may emit light whose wavelength is shorter than that of visible light. The light emitted from the light source may have a wavelength of 13.5 nm or shorter. The light source 30 may be an extreme ultraviolet (EUV) light source emitting light whose wavelength is 13.5 nm or an X-ray light source of a wavelength shorter than 13.5 nm.

A material layer 22 is disposed on the stage 20 as the etching target. The material layer 22 includes a two-dimensional material layer. The two-dimensional material layer may be a single layer or multiple layers, for example, a graphene layer or a MoS₂ layer. The material layer 22, as illustrated in FIG. 2, may include a substrate 22A, an insulating layer 22B, and a two-dimensional material layer 22C which are sequentially stacked. The two dimensional material layer 22C may be formed directly on the insulating layer 22B. Alternatively, the two dimensional material layer 22C may be formed on another substrate and then transferred on the insulating layer 22B.

A desired (and/or alternatively predetermined) pattern 40A is formed on the mask 40. The pattern 40A may be identical with the pattern which is to be formed on the two-dimensional material layer 22C. Light 32 emitted from the light source 30 passes through the mask 40 and is irradiated to the material layer 22. Here, the pattern 40A imprinted on the mask 40 is transferred on the two-dimensional material layer 22C of the material layer 22. As a result, the two-dimensional material layer 22C is patterned to have the same pattern as the pattern 40A imprinted on the mask 40.

The etching apparatus also includes a fluid inlet 44 and a fluid outlet 48. Through the fluid inlet 44, a fluid 46 is supplied over the material layer 22, more particularly over the two-dimensional material layer 22C. The fluid 46 may selectively react with the two-dimensional material layer 22C during the fluid 46 flows over the material layer 22. Specifically, the fluid 46 reacts with a portion where light 32A which has passed through the mask 40 is irradiated in the two-dimensional material layer 22C. The fluid 46 may be supplied over the material layer 22 before the light 32A is irradiated. The supplying of the fluid 46 and the irradiation of the light 32A may coincide. The fluid 46 may be supplied right after the light 32A is irradiated, which is rare in common use. The fluid outlet 48 absorbs and discharges a residue after the reaction of the fluid 36 supplied over the material layer 22 or absorbs and discharges a reaction product 50 (e.g., CO₂) by the reaction between the fluid 46 and the two-dimensional material layer 22C. The fluid 46 may be a gas or liquid fluid. The gas fluid, for example, may be oxygen or oxygen ion gas. The liquid fluid may include an element (e.g., oxygen) which may react with carbon (C) of graphene to form a gaseous substance, examples of which are H₂O, CH₃OH, or C₂H₅OH.

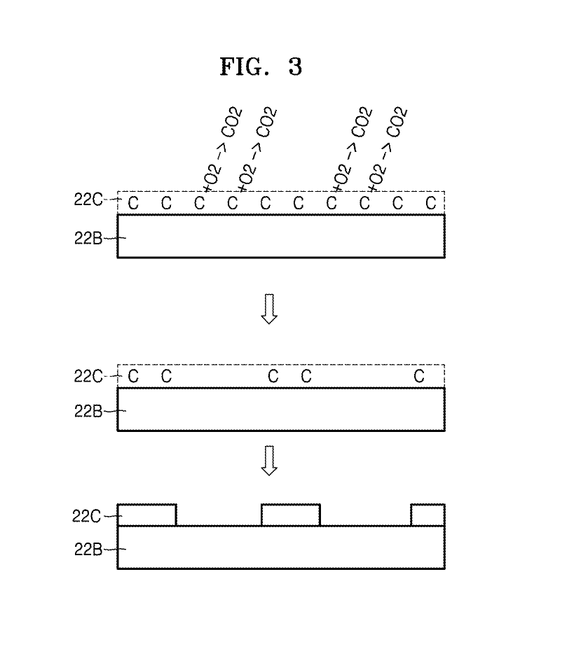

FIG. 3 illustrates an example of a reaction between the fluid 46 and the two-dimensional material layer 22C. Here, the two-dimensional material layer 22C is the graphene layer. The “C” indicates the carbon of graphene and the fluid 46 is oxygen gas (O₂).

Referring to FIG. 3, the O₂ reacts with the C of the portion where the light 32A has been irradiated in the two-dimensional material layer 22C to form a volatile substance, CO₂ as a reaction product. A fluid besides gas or liquid may also be used as the fluid 46 if the fluid may react with the two-dimensional material layer 22C to form the volatile reaction product as such. The portion which has reacted with O₂ in the two-dimensional material layer 22C is eliminated, which leads the two-dimensional material layer 22C to be patterned in a desired (and/or alternatively predetermined) form.

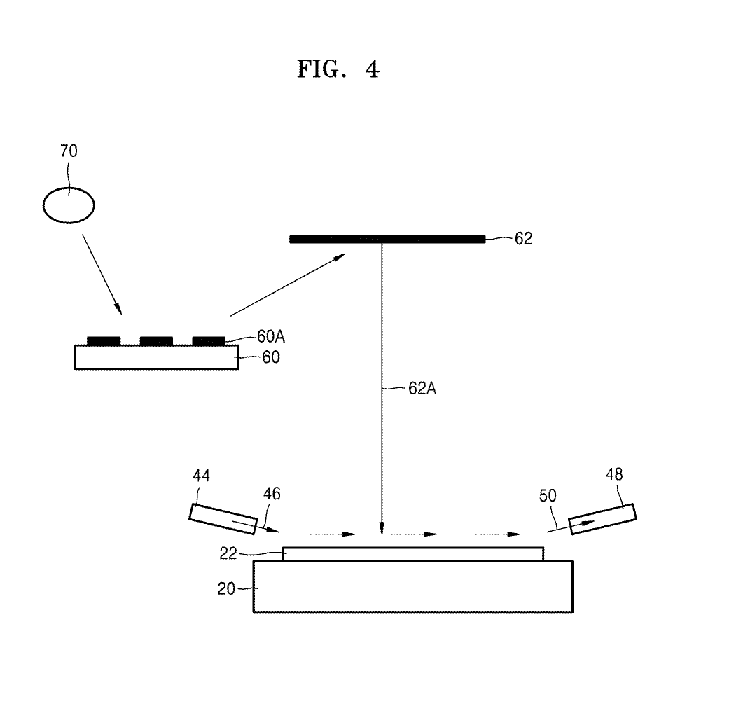

FIG. 4 illustrates an etching apparatus according to example embodiments.

Referring to FIG. 4, the etching apparatus includes a light source 70, a mask 60, a reflector 62, a stage 20, a fluid inlet 44 and a fluid outlet 48. The reflector 62 may face the stage 20. The reflector 62 may be a mirror. The stage 20, the fluid inlet 44, and the fluid outlet 48 may be identical with those described in the etching apparatus of FIG. 1. The light source 70 may emit EUV, that is to say, may be an EUV light source. The mask 60 may be a reflecting mask which reflects the EUV. The mask 60 may have a disposition in which light emitted from the light source 70 is reflected to the reflector 62. A pattern 60A is formed on the mask 60. The pattern 60A may be the pattern which is to be formed on the two-dimensional material layer 22C. The pattern 60A imprinted on the mask 60 may be transferred on the two-dimensional material layer 22C of the material layer 22 as the light 62A reflected from the reflector 62 is irradiated on a material layer 22. As illustrated in FIG. 3, it is a result of the reaction between the fluid 46 and the irradiated portion in the two-dimensional material layer 22C that the pattern 60A is formed on the two-dimensional material layer 22C. The role of the fluid inlet 44 and the fluid outlet 48 in the etching apparatus of FIG. 4 may be identical with the one described in the etching apparatus of FIG. 1.

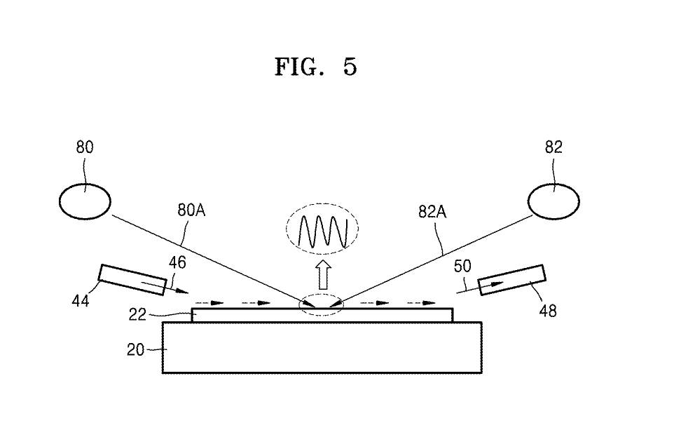

FIG. 5 illustrates an etching apparatus according to example embodiments.

Referring to FIG. 5, the etching apparatus includes a stage 20, a first light source 80, and a second light source 82. The first and the second light sources 80 and 82 may be the EUV light source or the X-ray light source as described above. The etching apparatus of FIG. 5 may include the gas inlet 44 and the gas outlet 48 of FIG. 1, which are not illustrated for convenience in FIG. 5. The stage 20 may be identical with the one described in FIG. 1. A material layer 22 is present on the stage 20. The first and the second light sources 80 and 82 disposed apart therefrom may be a light source which forms an interference pattern for patterning a two-dimensional material layer 22C of the material layer 22. The light beams 80A and 82A are irradiated from the first and the second light sources 80 and 82 to a region where the pattern of the two-dimensional material layer 22C is to be formed. A fluid 46 may be supplied before the light beams 80A and 82A are irradiated. Or the supplying of the fluid 46 may coincide with the irradiation of the light beams 80A and 82A. Or the fluid 46 may be supplied right after the light beams 80A and 82A are irradiated. As illustrated in FIG. 5, the interference pattern is formed in the region by the irradiated light beams 80A and 82A. In the interference pattern, the two-dimensional material layer 22C is etched by parts with high light intensity, that is, crests and is not etched by troughs. The pattern is formed on the two-dimensional material layer 22C as such.

The etching apparatus of FIG. 5 does not need the mask, and therefore the composition of the etching apparatus may become simpler.

Meanwhile, a pressure of a chamber including the above-described elements in the etching apparatus of FIGS. 1, 4, and 5 may be lower than air pressure (e.g., atm pressure). Also, the fluid outlet 48 may be used as a pumping unit for lowering the pressure of the chamber.

As described above, according to example embodiments, graphene patterning where chemicals such as photoresist are not used may limit (and/or prevent) degradation of a graphene film due to pollution in a patterning process. As X-ray or EUV are used as light sources without an electron beam being used, productivity may be raised compared to a graphene direct patterning technology based on electron beam lithography. Accordingly, example embodiments may be applied to processes for manufacturing graphene devices.

It should be understood that example embodiments described herein should be considered in a descriptive sense only and not for purposes of limitation. Descriptions of features or aspects within each apparatus or method according to example embodiments should typically be considered as available for other similar features or aspects in other apparatuses or methods according to example embodiments. While some example embodiments have been particularly shown and described, it will be understood by one of ordinary skill in the art that variations in form and detail may be made therein without departing from the spirit and scope of the claims.

What is claimed is:

1. An apparatus for etching a two-dimensional material, the apparatus comprising:
a stage configured to support an etching target including graphene on the stage;
a light source configured to emit light having a wavelength that is shorter than a wavelength of visible light;
a mask imprinted with a pattern for transferring to the etching target;
a fluid inlet configured to supply fluid over the etching target through the fluid inlet,
a fluid outlet configured to absorb a residue and a reaction product after the fluid is supplied over the etching target using the fluid inlet.

2. The apparatus of claim 1, wherein the light source is an extreme ultraviolet (EUV) light source, or an X-ray light source.

3. The apparatus of claim 1, wherein the mask is a transmitting mask that is configured to transmit light incident from the light source.

4. The apparatus of claim 1, wherein the mask is a reflecting mask that is configured to reflect light incident from the light source.

5. The apparatus of claim 4, further comprising:
a reflector configured to reflects the light incident from the reflecting mask to the etching target.

6. The apparatus of claim 1, wherein
the fluid is a gas or a liquid fluid, and
the fluid reacts with the etching target to form a volatile reaction product.

7. The apparatus of claim 6, wherein the gas fluid is oxygen or an oxygen ion.

8. The apparatus of claim 6, wherein the liquid fluid includes an element that reacts with carbon (C) of the graphene to form a gaseous substance.

9. An apparatus for etching a two-dimensional material, the apparatus comprising:
a stage configured to support an etching target including graphene on the stage;
a first light source configured to irradiate the first light on a first region of the etching target;
a second light source configured to emit a second light that forms an interference pattern with the first light in the first region;
a fluid inlet configured to supply a fluid over the etching target; and
a fluid outlet configured to absorb a residue and a reaction product after the fluid is supplied over the etching target using the fluid inlet.

10. The apparatus of claim 9, wherein
the fluid is a gas or a liquid fluid, and
the fluid reacts with the etching target to form a volatile reaction product.

11. The apparatus of claim 10, wherein the gas fluid is oxygen or an oxygen ion.

12. The apparatus of claim 10, wherein the liquid fluid includes an element that reacts with carbon (C) of the graphene to form a gaseous substance.

13. A method of patterning a two-dimensional material layer, the method comprising:
disposing an etching target on a stage, the etching target including graphene;
irradiating light on the etching target, the light having a wavelength that is shorter than a wavelength of visible light;
supplying a fluid over the etching target; and
removing a fluid residue and a fluid reaction product on the etching target.

14. The method of claim 13, wherein the irradiating the light on the etching target includes irradiating light incident from a mask.

15. The method of claim 13, wherein the fluid is supplied before the irradiating light on the etching target.

16. The method of claim 13, wherein the supplying the fluid and the irradiating light on the etching target are performed simultaneously.

17. The method of claim 14, wherein the mask is a transmitting mask or reflecting mask.

18. The method of claim 13, wherein the fluid is a gas or a liquid fluid that reacts with the etching target to form a volatile reaction product.

19. A method of patterning a two-dimensional material layer, the method comprising:
disposing an etching target on a stage, the etching target including graphene;
irradiating first light on a first region of the etching target, the first light having a wavelength that is shorter than a wavelength of visible light;
irradiating second light on the first region of the etching target, the second light forming an interference pattern with the first light on the first region, the second light having a wavelength that is shorter than the wavelength of visible light;
supplying a fluid over the etching target; and
removing a fluid residue and a fluid reaction product from the etching target.

20. The method of claim 19, wherein
the supplying the fluid is performed before the first and the second light are irradiated on the first region of the etching target, or
the supplying the fluid, the irradiating first light, and the irradiating second light are performed simultaneously.
